(19) United States
(12) Patent Application Publication
(10) Pub. No.: US 2006/0261381 A1
(43) Pub. Date: Nov. 23, 2006

(54) Photodetector

(75) Inventor: Yu-Zung Chiou, Kaohsiung City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Southern Taiwan University of Technology

(21) Appl. No.: 11/393,266

(22) Filed: Mar. 30, 2006

(30) Foreign Application Priority Data
May 18, 2005 (TW) 94116163

(51) Int. Cl. H01L 31/112

(52) U.S. Cl. 257/257

(57) ABSTRACT

A photodetector is disclosed, comprising: a substrate; a GaN-related material layer of a first conductivity type located on the substrate; an intrinsic layer located on a portion of the GaN-related material layer of the first conductivity type; a first GaN-related material layer of a second conductivity type located on the intrinsic layer; a second GaN-related material layer of the second conductivity type located on the first GaN-related material layer of the second conductivity type; an electrode of the second conductivity type located on a portion of the second GaN-related material layer of the second conductivity type; and an electrode of the first conductivity type located on another portion of the GaN-related material layer of the first conductivity type.

### RELATED APPLICATIONS

The present application is based on, and claims priority from, Taiwan Application Serial Number 94116163, filed May 18, 2005, the disclosure of which is hereby incorporated by reference herein in its entirety.

### FIELD OF THE INVENTION

The present invention relates to a photodetector, and more particularly, to a nitride gallium-based p-i-n band pass photodetector.

### BACKGROUND OF THE INVENTION

Photodetectors are semiconductor devices, which can detect an incident light by transforming optical signals into electronic signals. In the photodetectors, because the ultraviolet (UV) detector can be applied in space communication, crack detecting of ozonosphere, and detecting of ultraviolet ray index, and the application of the UV detector is very broadly, the study about the UV detector is quite visible.

Conventionally, an UV detector is a device mainly made of silicon. The band-gap of silicon is only about 1.12 eV, but the band-gap of the material used to detect UV radiation needs to be greater than the band-gap 3.18 eV of UV photo energy. For example, when UV detector made of silicon is used to detect light, the signals from UV light, visible light, even far infrared light can be detected. However, an ideal UV detector should be only sensitive to the UV signal, and have poor sensitive to the signals from visible light and far infrared light, which is so-called solar-blind or visible-blind detector.

It is not appropriate for using silicon to make UV detector. Therefore, it is a need for a photodetector that can detect a particular wavelength section of light, which is suitable to UV light or light with other wavelength sections.

### SUMMARY OF THE INVENTION

Therefore, one objective of the present invention is to provide a photodetector, in which the photodetector can detect the incident light with a particular section of wavelength, so that it is beneficial to sift and filter light.

Another objective of the present invention is to provide a photodetector, having a thick p-type or n-type semiconductor blocking layer, so the incident light with higher energy can be absorbed firstly, to prevent the high energy incident light from entering the intrinsic layer, and avoid the photodetector from being unexpectedly triggered by a great quantity of high energy incident light, thereby the accuracy of photodetector can be effectively enhanced.

Still another objective of the present invention is to provide a photodetector, in which the optical bandwidth and the detected wavelength range of light of the photodetector can be adjusted by changing the composition of the thick p-type or n-type semiconductor blocking layer and the intrinsic layer. Therefore, suitable photodetectors for various wavelength sections can be easily manufactured.

According to the aforementioned objectives, the present invention provides a photodetector, comprising: a substrate; a GaN-related material layer of a first conductivity type located on the substrate; an intrinsic layer located on a portion of the GaN-related material layer of the first conductivity type; a first GaN-related material layer of a second conductivity type located on the intrinsic layer; a second GaN-related material layer of the second conductivity type located on the first GaN-related material layer of the second conductivity type; an electrode of the second conductivity type located on a portion of the second GaN-related material layer of the second conductivity type; and an electrode of the first conductivity type located on the other portion of the GaN-related material layer of the first conductivity type.

According to a preferred embodiment of the present invention, a material of the GaN-related material layer of the first conductivity type can be first conductivity type GaN, a material of the intrinsic layer can be undoped GaN, undoped Al_{y}Ga_{1-y}N or undoped In_{z}Ga_{1-z}N, a material of the first GaN-related material layer of the second conductivity type can be second conductivity type AlₓGa₁₋ₓN or second conductivity type In_{z}Ga_{1-z}N, and a material of the second GaN-related material layer of the second conductivity type can be second conductivity type GaN. In addition, a thickness of the first GaN-related material layer of the second conductivity type is preferably between about 6 nm and about 2 μm.

By adjusting the mole ratio of aluminum in the first GaN-related material layer of the second conductivity type and the intrinsic layer, photodetectors of various wavelength sections can be obtained, thus it is beneficial for the filtering of incident light in various wavelength sections.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 illustrates a cross-sectional view of a photodetector in accordance with a preferred embodiment of the present invention.

FIG. 2 illustrates a cross-sectional view of a photodetector in accordance with another preferred embodiment of the present invention.

### DETAILED DESCRIPTION OF THE PREFERRED EMBODIMENT

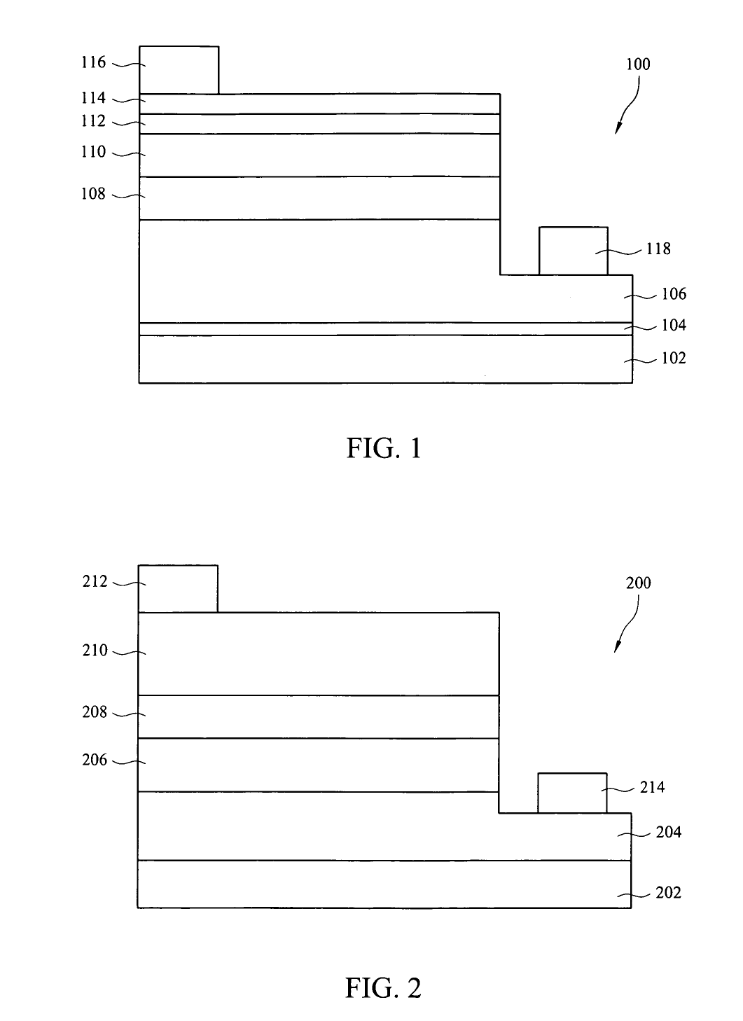

The present invention discloses a photodetector having a thicker p-type or n-type semiconductor blocking layer, so that the incident light with a particular section of wavelength can be detected accurately. In order to make the illustration of the present invention more explicit and complete, the following description is stated with reference to FIGS. 1 and 2.

Because there is no desirable photodetector suitable for detecting light in various wavelength sections, the present invention provide a photodetector manufactured by using wide band-gap materials. The wide band-gap materials can be almost totally passed through and is not absorbed by the light with wavelengths except for ultraviolet, so the wide band-gap materials are suitable for manufacturing an UV detector. In these wide band-gap materials, GaN is visible due to GaN has excellent physical and electrical properties in high-temperature, high-power, high frequency and radiation properties applications. Presently, photodiodes made of GaN materials includes p-n junction diode, p-i-n diode, schottky barrier detector and metal-semiconductor-metal photodetector.

The present invention uses, for example, a metal organic chemical vapor deposition (MOCVD) process to epitaxially grow a GaN-based p-i-n bandpass photodiode as a photodetector.

Referring to FIG. 1, FIG. 1 illustrates a cross-sectional view of a photodetector in accordance with a preferred embodiment of the present invention. In the manufacturing of a photodetector 100 of the present invention, a pretreatment step is performed on a substrate 102 firstly, and an annealing step is performed on the substrate 102 at a reactive temperature of about 1150° C. in H₂ ambiance to remove the contaminants on a surface of the substrate 102. A material of the substrate 102 can be, for example, sapphire, Si, SiO₂ or ZnSe, and sapphire is preferably. Next, a low temperature buffer layer 104 is deposited on the substrate by using, for example, a metal organic chemical vapor deposition method, in which a material of the buffer layer 104 is GaN-related material layer, such as GaN, and a thickness of the buffer layer 104 is preferably between about 25 nm and about 50 nm . In the deposition of the buffer layer 104, trimethylgallium (TMGa) and NH₃, for example, can be respectively used as source materials of gallium and nitrogen, hydrogen gas can be used as a carrier gas, and a reactive temperature is preferably controlled at 550° C.

Then, the reactive temperature is raised to about 1050° C., and a GaN-related material layer of a first conductivity type 106 is deposited on the buffer layer 104 by, for example, a metal organic chemical vapor deposition method, in which a material of the GaN-related material layer of the first conductivity type 106 can be preferably a first conductivity type GaN-based material, such as first conductivity type GaN, and a thickness of the GaN-related material layer of the first conductivity type 106 is preferably between about 3.5 μm and about 5 μm. In the forming of the GaN-related material layer of the first conductivity type 106, trimethylgallium and NH₃, for example, can be respectively used as source materials of gallium and nitrogen, hydrogen gas can be used as a carrier gas, and disilane (Si₂H₆) can be used as first conductivity type dopant. In the present invention, the first conductivity type may be n-type or p-type. After the GaN-related material layer 106 of the first conductivity type is formed, an intrinsic layer 108 is deposited on the GaN-related material layer of the first conductivity type 106 by, for example, a metal organic chemical vapor deposition method. A material of the intrinsic layer 108 can be preferably undoped GaN, undoped Al_{y}Ga_{1-y}N or undoped In_{z}Ga_{1-z}N, for example, and a thickness of the intrinsic layer 108 is preferably between about 0.3 μm and about 3 μm.

Next, a GaN-related material layer of the second conductivity type 110 is deposited on the intrinsic layer 108 by, for example, a metal organic chemical vapor deposition method. A material of the GaN-related material layer of the second conductivity type 110 can be preferably In_{z}Ga_{1-z}N or AlₓGa₁₋ₓN, such as Al_{0.1}Ga_{0.9}N, and a thickness of the GaN-related material layer of the second conductivity type 110 is preferably between about 6 nm and about 2 μm. In the deposition of the GaN-related material layer of the second conductivity type 110, trimethylgallium and NH₃, for example, can be respectively used as source materials of gallium and nitrogen, hydrogen gas can be used as a carrier gas, and bicyclopentadienyl (CP₂Mg) can be used as second conductivity type dopant. In the present invention, the second conductivity type may be p-type or n-type, and the first conductivity type and the second conductivity type are opposite conductivity types. When the first conductivity type is n-type, the second conductivity type is p-type; and when the first conductivity type is p-type, the second conductivity type is n-type. For example, in the present embodiment, the first conductivity type is n-type, and the second conductivity type is p-type.

In a preferred embodiment of the present, the material of the GaN-related material layer of the second conductivity type 110 is AlₓGa₁₋ₓN, and the material of the intrinsic layer 108 is undoped Al_{y}Ga_{1-y}N. By changing the mole ratio x and y of aluminum respectively in the GaN-related material layer of the second conductivity type 110 and the intrinsic layer 108, the detected wavelength section of light of the photodetector 100 can be adjusted. For example, when the mole ratio x of aluminum in the GaN-related material layer of the second conductivity type 110 is increased, the detected wavelength range of light of the photodetector 100 is expanded outwardly to shorter wavelength; and when the mole ratio x of aluminum in the GaN-related material layer of the second conductivity type 110 is decreased, the detected wavelength range of light of the photodetector 100 is shrunk inwardly to longer wavelength. In addition, when the mole ratio y of aluminum in the intrinsic layer 108 is increased, the detected wavelength range of light of the photodetector 100 is shrunk inwardly to shorter wavelength; and when the mole ratio y of aluminum in the intrinsic layer 108 is decreased, the detected wavelength range of light of the photodetector 100 is expanded outwardly to longer wavelength. In another word, one boundary of the detected wavelength range of light is controlled by the variation of the mole ratio x of aluminum in the GaN-related material layer of the second conductivity type 110, and the other boundary of the detected wavelength range of light is controlled by the variation of the mole ratio y of aluminum in the intrinsic layer 108. Accordingly, the optical bandwidth and the detected wavelength range of light of the photodetector 100 can be adjusted by changing the composition of the GaN-related material layer of the second conductivity type 110 and the intrinsic layer 108. Therefore, one feature of the present invention is that, for various wavelength sections, the suitable photodetector 100 can be easily manufactured.

Then, a GaN-related material layer of the second conductivity type 112 is deposited on the GaN-related material layer of the second conductivity type 110 by, for example, a metal organic chemical vapor deposition method, similarly, so as to form an epitaxy structure on the substrate 102. A material of the GaN-related material layer of the second conductivity type 112 can be preferably a second conductivity type GaN-based material, such as second conductivity type GaN, and a thickness of the GaN-related material layer of the second conductivity type 112 is preferably between about 10 nm and about 80 nm . Similarly, in the deposition of the GaN-related material layer of the second conductivity type 112, trimethylgallium and NH₃, for example, can be respectively used as source materials of gallium and nitrogen, hydrogen gas can be used as a carrier gas, and bicyclopentadienyl can be used as second conductivity type dopant.

After the GaN-related material layer of the second conductivity type 112 is formed, a portion of the GaN-related material layer of the second conductivity type 112, a portion of the GaN-related material layer of the second conductivity type 110 and a portion of the intrinsic layer 108 are removed by, for example, an inductance coupled plasma (ICP) method, until a portion of the GaN-related material layer of the first conductivity type 106 is exposed. In order to assure the process reliability, a portion of the exposed GaN-related material layer of the first conductivity type 106 is also removed. Subsequently, the epitaxy structure is cleaned by using, for example, acetone, pure hydrochloric acid and de-ionized water in sequence.

After the epitaxy structure is cleaned, an electrode of the second conductivity type 116 can be directly formed on the GaN-related material layer of the second conductivity type 112 by, for example, an E-beam evaporation method. Alternatively, a transparent ohmic contact layer 114 can be firstly formed to cover the GaN-related material layer of the second conductivity type 112 by, for example a deposition method, and then the electrode of the second conductivity type 116 is formed on a portion of the transparent ohmic contact layer 114. The material of the transparent ohmic contact layer 114 is a material can have good ohmic contact with the GaN-related material layer of the second conductivity type 112, and the material of the transparent ohmic contact layer 114 is preferably metal or metal oxide, such as ITO or IZO. The material of the electrode of the second conductivity type 116 is preferably a material that can have good ohmic contact with the GaN-related material layer of the second conductivity type 112 and the transparent ohmic contact layer 114, and the material of the electrode of the second conductivity type 116 can be such as ITO, Ni/ITO, Ni/Au or Pd/Au. In one embodiment of the present invention, a specific contact resistance of the electrode of the second conductivity type 116 is estimated to be about 8.7×10⁻³ Ohms-cm² by a circular transmission line measurement (CTLM). In addition, an electrode of the first conductivity type 118 is formed on the exposed portion of the GaN-related material layer of the first conductivity type 106 by, for example, an E-beam evaporation method, to complete the manufacture of the photodetector 100 of the present invention. The electrode of the first conductivity type 118 can be an Al/Ti/Au stacked structure, or a Ti/Al/Ti/Au stacked structure.

Referring to FIG. 2, FIG. 2 illustrates a cross-sectional view of a photodetector in accordance with another preferred embodiment of the present invention. In the embodiment, a manufacturing method and materials adopted for an photodiode epitaxy structure of a photodetector 200 are substantially the same with that used in the foregoing embodiment, and the two embodiments both grow use a metal organic chemical vapor deposition process to epitaxially grow a GaN-based p-i-n bandpass photodiode on a substrate. In the growing of the epitaxy structure, trimethylgallium, trimethylindium (TMIn) and NH₃ can be respectively used as source materials of gallium, indium and nitrogen. In the metal organic chemical vapor deposition process, hydrogen gas can be used as a carrier gas, disilane can be used as first conductivity type dopant, and bicyclopentadienyl can be used as second conductivity type dopant. In the present invention, the first conductivity type and the second conductivity type may be p-type or n-type, and the first conductivity type and the second conductivity type are opposite conductivity types. When the first conductivity type is n-type, the second conductivity type is p-type; and when the first conductivity type is p-type, the second conductivity type is n-type. For example, in the present embodiment, the first conductivity type is n-type, and the second conductivity type is p-type.

The photodetector 200 is formed on a transparent substrate 202, in which a material of the transparent substrate 202 is preferably sapphire. A photodiode epitaxy structure is formed on the transparent substrate 202, in which the photodiode epitaxy structure comprises: a GaN-related material layer of the second conductivity type 204 located on the transparent substrate 202, a GaN-related material layer of the second conductivity type 206 located on a portion of the GaN-related material layer of the second conductivity type 204, an intrinsic layer 208 located on the GaN-related material layer of the second conductivity type 206, and a GaN-related material layer of the first conductivity type 210 located on the intrinsic layer 208. A p-i-n diode structure is composed of the GaN-related material layer of the second conductivity type 206, the intrinsic layer 208 and the GaN-related material layer of the first conductivity type 210. Besides, an electrode of the first conductivity type 212 is located on a portion of the GaN-related material layer of the first conductivity type 210, and a electrode of the second conductivity type 214 is located on the exposed portion of the GaN-related material layer of the second conductivity type 204. Similar to photodetector 100, in the photodetector 200, a material of the GaN-related material layer of the second conductivity type 204 can be preferably a second conductivity type GaN-based material, such as second conductivity type GaN, and a thickness of the GaN-related material layer of the second conductivity type 204 is preferably between about 10 nm and about 80 nm . A material of the GaN-related material layer of the second conductivity type 206 can be preferably In_{z}Ga_{1-z}N or AlₓGa₁₋ₓN, such as Al_{0.1}Ga_{0.9}N, a thickness of the GaN-related material layer of the second conductivity type 206 is preferably between about 6 nm and about 2 μm. A material of the intrinsic layer 208 can be preferably undoped GaN, undoped Al_{y}Ga_{1-y}N or undoped In_{z}Ga_{1-z}N, for example, and a thickness of the intrinsic layer 208 is preferably between about 0.3 μm and about 3 μm. A material of the GaN-related material layer of the first conductivity type 210 can be preferably a first conductivity type GaN-based material, such as first conductivity type GaN, and a thickness of the GaN-related material layer of the first conductivity type 210 is preferably between about 3.5 μm and about 5 μm. The electrode of the first conductivity type 212 can be an Al/Ti/Au stacked structure, or a Ti/Al/Ti/Au stacked structure. The material of the electrode of the second conductivity type 214 is preferably a material that can have good ohmic contact with the GaN-related material layer of the second conductivity type 204, and the material of the electrode of the second conductivity type 214 can be such as ITO, Ni/ITO, Ni/Au or Pd/Au.

In the application, the direction of the incident light to photodetector 100 is opposite to that of the incident light to photodetector 200. When the photodetector 100 is used to detect an incident light, the incident direction of the incident light is from the top of the transparent ohmic contact layer 114 to the substrate 102. On the contrary, when the photodetector 200 is used to detect an incident light, the incident direction of the incident light is from the transparent substrate 202 to the GaN-related material layer of the first conductivity type 210. Accordingly, the photodetector 200 needs to be formed on the transparent substrate 202, and the photodetector 100 can be formed on an opaque substrate.

The photodetector 100 is taken for example to illustrate the operation of using the photodetector of the present invention to detect an incident light. It is assumed that the detected wavelength section of light of the photodetector 100 is between 337 nm and 365 nm . When the wavelength of the incident light is less than 337 nm , because the band-gap of the thick GaN-related material layer of the second conductivity type 110 composed AlₓGa₁₋ₓN is larger than the energy of the incident light, and the thickness of the GaN-related material layer of the second conductivity type 110 is great, most of the photos of the incident light can be absorbed by the GaN-related material layer of the second conductivity type 110. Therefore, the intrinsic layer 108 under the GaN-related material layer of the second conductivity type 110 cannot be effectively activated by the incident light, and the current is not induced. When the wavelength of the incident light is larger than 365 nm , because the energy of the incident light is less than the band-gap of the GaN-related material layer of the second conductivity type 110 and the band-gap of the intrinsic layer 108, the incident light cannot be absorbed by the GaN-related material layer of the second conductivity type 110 and the intrinsic layer 108. Accordingly, the intrinsic layer 108 is not activated by the incident light, and the current is not induced. When the wavelength of the incident light is between 337 nm and 365 nm , the energy of the incident light is less than the band-gap of the GaN-related material layer of the second conductivity type 110 and larger than the band-gap of the intrinsic layer 108, so the incident light is not absorbed by the GaN-related material layer of the second conductivity type 110 but is absorbed by the intrinsic layer 108. Therefore, the intrinsic layer 108 is activated by the incident light to form electron-hole pairs and induce current. Then, the incident light can be transformed into electrical signals, and the electrical signals are output to complete the detection of the incident light.

According to the aforementioned description, one advantage of the present invention is that the photodetector of the present invention can detect the incident light with a particular section of wavelength, so that it is beneficial to sift and filter the light.

According to the aforementioned description, another advantage of the present invention is that the photodetector of the present invention having a thick p-type or n-type semiconductor blocking layer, so the incident light with higher energy can be absorbed firstly, to prevent the high energy incident light from entering the intrinsic layer, and avoid the photodetector from being unexpectedly triggered by a great quantity of high energy incident light. Therefore, the accuracy of photodetector can be greatly enhanced.

According to the aforementioned description, still another advantage of the present invention is that the optical bandwidth and the detected wavelength range of light of the photodetector of the present invention can be flexibly adjusted by changing the composition of the thick p-type or n-type semiconductor blocking layer and the intrinsic layer. Therefore, suitable photodetectors for various wavelength sections can be easily manufactured.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A photodetector, comprising:
a substrate;
a GaN-related material layer of the first conductivity type located on the substrate;
an intrinsic layer located on a portion of the GaN-related material layer of the first conductivity type;
a first GaN-related material layer of a second conductivity type located on the intrinsic layer, wherein the first conductivity and the second conductivity type are opposite conductivity types;
a second GaN-related material layer of the second conductivity type located on the first GaN-related material layer of the second conductivity type;
an electrode of the second conductivity type located on a portion of the second GaN-related material layer of the second conductivity type; and
an electrode of the first conductivity type located on the other portion of the GaN-related material layer of the first conductivity type.

2. The photodetector according to claim 1, wherein a material of the substrate is selected from the group consisting of sapphire, Si, SiO₂ and ZnSe.

3. The photodetector according to claim 1, wherein a material of the GaN-related material layer of the first conductivity type is first conductivity type GaN.

4. The photodetector according to claim 1, wherein a thickness of the GaN-related material layer of the first conductivity type is between about 3.5 μm and about 5 μm.

5. The photodetector according to claim 1, wherein a material of the intrinsic layer is selected from the group consisting of undoped GaN, undoped Al_{y}Ga_{1-y}N and undoped In_{z}Ga_{1-z}N.

6. The photodetector according to claim 1, wherein a thickness of the intrinsic layer is between about 0.3 μm and about 3 μm.

7. The photodetector according to claim 1, wherein a material of the first GaN-related material layer of the second conductivity type is second conductivity type AlₓGa₁₋ₓN or second conductivity type In_{z}Ga_{1-z}N.

8. The photodetector according to claim 1, wherein a thickness of the first GaN-related material layer of the second conductivity type is between about 6 nm and about 2 μm.

9. The photodetector according to claim 1, wherein the first conductivity type is n-type and the second conductivity type is p-type.

10. The photodetector according to claim 1, wherein the first conductivity type is p-type and the second conductivity type is n-type.

11. The photodetector according to claim 1, wherein a material of the second GaN-related material layer of the second conductivity type is second conductivity type GaN.

12. The photodetector according to claim 1, wherein a thickness of the second GaN-related material layer of the second conductivity type is between about 10 nm and about 80 nm .

13. The photodetector according to claim 1, further comprises a transparent ohmic contact layer located on the second GaN-related material layer of the second conductivity type, wherein the transparent ohmic contact layer is located between the second GaN-related material layer of the second conductivity type and the electrode of the second conductivity type.

14. The photodetector according to claim 13, wherein a material of the transparent ohmic contact layer is selected from the group consisting of metal and metal oxide.

15. The photodetector according to claim 1, wherein a material of the electrode of the second conductivity type is selected from the group consisting of ITO, Ni/ITO, Ni/Au and Pd/Au.

16. The photodetector according to claim 1, wherein a material of the electrode of the first conductivity type is selected from the group consisting of Al/Ti/Au and Ti/Al/Ti/Au.

17. A photodetector, comprising:
a transparent substrate;
a first GaN-related material layer of a second conductivity type located on the transparent substrate;
a second GaN-related material layer of the second conductivity type located on a portion of the first GaN-related material layer of the second conductivity type;
an intrinsic layer located on the second GaN-related material layer of the second conductivity type;
a GaN-related material layer of a first conductivity type located on the intrinsic layer, wherein the first conductivity and the second conductivity type are opposite conductivity types;
an electrode of the first conductivity type located on the GaN-related material layer of the first conductivity type; and
an electrode of the second conductivity type located on the other portion of the first GaN-related material layer of the second conductivity type.

18. The photodetector according to claim 17, wherein a material of the transparent substrate is sapphire.

19. The photodetector according to claim 17, wherein a material of the first GaN-related material layer of the second conductivity type is second conductivity type GaN.

20. The photodetector according to claim 17, wherein a thickness of the first GaN-related material layer of the second conductivity type is between about 10 nm and about 80 nm .

21. The photodetector according to claim 17, wherein a material of the second GaN-related material layer of the second conductivity type is second conductivity type AlₓGa₁₋ₓN or second conductivity type In_{z}Ga_{1-z}N.

22. The photodetector according to claim 17, wherein a thickness of the second GaN-related material layer of the second conductivity type is between about 6 nm and about 2 μm.

23. The photodetector according to claim 17, wherein a material of the intrinsic layer is selected from the group consisting of undoped GaN, undoped Al_{y}Ga_{1-y}N and undoped In_{z}Ga_{1-z}N.

24. The photodetector according to claim 17, wherein a thickness of the intrinsic layer is between about 0.3 μm and about 3 μm.

25. The photodetector according to claim 17, wherein a material of the GaN-related material layer of the first conductivity type is first conductivity type GaN.

26. The photodetector according to claim 17, wherein a thickness of the GaN-related material layer of the first conductivity type is between about 3.5 μm and about 5 μm.

27. The photodetector according to claim 17, wherein a material of the electrode of the first conductivity type is selected from the group consisting of Al/Ti/Au and Ti/Al/Ti/Au.

28. The photodetector according to claim 17, wherein a material of the electrode of the second conductivity type is selected from the group consisting of ITO, Ni/ITO, Ni/Au and Pd/Au.

29. The photodetector according to claim 17, wherein the first conductivity type is n-type and the second conductivity type is p-type.

30. The photodetector according to claim 17, wherein the first conductivity type is p-type and the second conductivity type is n-type.
